(19) United States
(12) Patent Application Publication
(10) Pub. No.: US 2026/0349397 A1
(43) Pub. Date: Nov. 5, 2026

(54) FUZZY HYSTERESIS CONTROL METHOD AND CIRCUIT FOR HIGH-POWER, HIGH-STABILITY REMOTE PLASMA SOURCE

(71) Applicant: JIANGSU SHENZHOU SEMICONDUCTOR TECHNOLOGY CO., LTD, Yangzhou (CN)

(72) Inventors: Xiaogang PAN, Yangzhou (CN); Xiaojun GU, Yangzhou (CN); Yinzhi SHU, Yangzhou (CN); Peiwen ZHU, Yangzhou (CN)

(73) Assignee: JIANGSU SHENZHOU SEMICONDUCTOR TECHNOLOGY CO., LTD, Yangzhou (CN)

(21) Appl. No.: 19/337,967

(22) Filed: Sep. 24, 2025

(30) Foreign Application Priority Data
Apr. 21, 2025 (CN) 2025104951682

(51) Int. Cl. G05B 13/02; H01J 37/32; H02M 3/335

(52) U.S. Cl. CPC G05B 13/0275; H01J 37/321; H01J 37/32146; H01J 37/32174; H02M 3/33515

(57) ABSTRACT

A fuzzy hysteresis control method for a high-power, high-stability remote plasma source includes: controlling a plasma source system to operate in a constant-power output mode with a fixed frequency and a variable duty cycle when a reaction chamber is ignited, including: acquiring error control variables based on a sampled current value and a sampled duty cycle and a predicted current value and a predicted duty cycle, respectively; taking the error control variables as input values of a fuzzy controller, and acquiring an actual control variable hr output by the fuzzy controller; acquiring compensation variables α(e) and α(ec) for a current value and a duty cycle based on the error control variables; and taking the actual control variable as a hysteresis bandwidth value of a hysteresis comparator, and compensating, according to a preset rule, a current value iₚᵣᵢ(k) and a duty cycle d(k) at a time k with the output compensation variables α(e) and α(ec), respectively.

### CROSS REFERENCE TO THE RELATED APPLICATIONS

This application is based upon and claims priority to Chinese Patent Application No. 202510495168.2, filed on Apr. 21, 2025, the entire contents of which are incorporated herein by reference.

### TECHNICAL FIELD

The present disclosure relates to the technical field of plasma sources, and in particular to a fuzzy hysteresis control method and circuit for a high-power, high-stability remote plasma source.

### BACKGROUND

As a new technology that utilizes high-energy plasma for material processing, plasma technology has been widely applied in fields such as industrial semiconductors, biomedicine, and the food environment. Due to high efficiency, high flexibility, and sustainability, remote plasma sources are increasingly used in processes such as surface cleaning, modification, and deposition of various materials, and their application prospects are becoming broader. However, existing remote plasma source systems generally suffer from problems such as low power supply output power, limited types of available gases for ionization, small gas flow range, and unstable plasma concentration, which cause poor process uniformity and etching rate. Additionally, when large samples or large batches are processed, the methods of multi-source parallel connection and multi-stage series connection can increase the power supply power and processing efficiency but introduce difficulties in synchronous control of remote plasma sources.

Overall, existing remote plasma source systems generally suffer from problems such as low power supply output power, limited types of available gases for ionization, small gas flow range, and unstable plasma concentration. When large samples or large batches are processed, the methods of multi-source parallel connection and multi-stage series connection can increase the power supply power and processing efficiency but introduce problems such as resource waste, poor uniformity, and difficulties in synchronous control. Therefore, ensuring the operational stability of each system and the accuracy of control variables during the process of increasing plasma source power has become an urgent problem to be solved by those skilled in the art.

### SUMMARY

In view of the defects in the prior art, the present disclosure provides a fuzzy hysteresis control method and circuit for a high-power, high-stability remote plasma source to solve the problem of low output power in existing remote plasma source systems.

A first aspect of the present disclosure provides a fuzzy hysteresis control method for a high-power, high-stability remote plasma source, including: controlling a plasma source system to operate in a constant-power output mode with a fixed frequency and a variable duty cycle when a reaction chamber is successfully ignited, including:
acquiring error control variables e and ec based on a sampled current value and a sampled duty cycle and a predicted current value and a predicted duty cycle, respectively, where, e=iₚᵣᵢ(k+1)−iₚᵣᵢ(k), ec=d(k+1)−d(k); iₚᵣᵢ(k) and d(k) denote a sampled current value and a sampled duty cycle at a time k, respectively; and iₚᵣᵢ(k+1) and d(k+1) denote a predicted sampled current value and duty cycle at a time k+1, respectively;
taking the error control variables e and ec as input values of a fuzzy controller, and acquiring an actual control variable hr output by the fuzzy controller;
acquiring a compensation variable α(e) for the predicted current value at the next time and a compensation variable α(ec) for the predicted duty cycle at the next time based on the error control variables e and ec; and
taking the actual control variable hr as a hysteresis bandwidth value of a hysteresis comparator; and compensating, according to a preset rule, the current value iₚᵣᵢ(k) and the duty cycle d(k) at the time k with the output compensation variables α(e) and α(ec), respectively.

As can be seen from the above technical solution, the method provided by the present disclosure combines fuzzy control and the variable-bandwidth hysteresis comparator for control, and feedback compensation is applied to the output current value iₚᵣᵢ and duty cycle D. The present disclosure can improve the power adjustment accuracy of the system, ensure a wide power range, enhance the operational stability of the remote plasma source, and improve the uniformity of semiconductor manufacturing processes.

Optionally, when the current value iₚᵣᵢ(k) at the current time is compensated with the output compensation variable α(e), the preset rule includes:
when a power error satisfies P_{ref}−Pₒ>hr, the variable α(e) is subtracted from the current value iₚᵣᵢ(k) at the current time and fed back to compensate the output current value iₚᵣᵢ(k+1) at the next time;
when the power error satisfies −hr≤P_{ref}−Pₒ≤hr, iₚᵣᵢ(k+1) at the time k+1 is maintained consistent with iₚᵣᵢ(k) at the time k; and
when the power error satisfies P_{ref}−Pₒ<−hr, the variable α(e) is added to the current value iₚᵣᵢ(k) at the current time and fed back to compensate the output current value iₚᵣᵢ(k+1) at the next time.

Optionally, when the duty cycle d(k) at the current time is compensated with the output compensation variable α(ec), the preset rule includes:
when a current error satisfies i_{ref}−iₚᵣᵢ>hr, the variable α(ec) is subtracted from the duty cycle d(k) at the current time and fed back to compensate the output duty cycle d(k+1) at the next time;
when the current error satisfies −hr≤i_{ref}−iₚᵣᵢ≤hr, a switch transistor state of a previous time is maintained to keep the duty cycle D relatively stable; and
when the current error satisfies i_{ref}−iₚᵣᵢ<−hr, the variable α(ec) is added to the duty cycle d(k) at the current time and fed back to compensate the output duty cycle d(k+1) at the next time.

Optionally, iₚᵣᵢ(k+1) at the time k+1 is predicted as follows:
expressing a normalized value ωₙ of a resonant frequency ω₀ and a switching frequency ω of a resonant converter as follows:
ω₀=1/\sqrt{LᵣCᵣ}; ωₙ=ω/ω₀=2fₛ \sqrt{LᵣCᵣ}; where, fₛ denotes an output frequency;
expressing an equivalent resistance R_{L} and a root mean square (RMS) value of a fundamental component of an input square wave voltage expressed as follows:

$${R}_{L} = {n}^{2} {R}_{p} ; {U}_{ab} = \frac{2 \sqrt{2}}{π} {U}_{in} ;$$

expressing an inductance ratio λ, a characteristic impedance Z₀, and a quality factor Q of an equivalent circuit as follows:

$$λ = \frac{{L}_{k}}{{L}_{r}} ; {Z}_{0} = \sqrt{\frac{{L}_{r}}{{C}_{r}}} ; Q = \frac{{ω}_{0} {L}_{r}}{{R}_{p}} = \frac{{Z}_{0}}{{n}^{2} {R}_{p}} = \sqrt{\frac{{L}_{r}}{{C}_{r}}} / {R}_{L} ;$$

where, Lᵣ, Cᵣ, and Lₖ denote a resonant inductance, a resonant capacitance, and a leakage inductance of the resonant converter, respectively;
expressing a primary winding current value iₚᵣᵢ and a voltage Vₗₒₒₚ as follows:

$${i}_{pri} = \frac{{U}_{ab}}{{Z}_{0}} \frac{Q}{( 1 - {ω}_{n}^{2} ) + jQ [ ( 1 + λ ) {ω}_{n} - {λω}_{n}^{3} ]} ;$$

$${V}_{loop} = {U}_{ab} \frac{1}{( 1 - {ω}_{n}^{2} ) + jQ [ ( 1 + λ ) {ω}_{n} - {λω}_{n}^{3} ]} ;$$

predicting the primary winding current value at the time k+1 as

$${i}_{pri} ( k + 1 ) = \frac{{U}_{ab}}{{Z}_{0}} \frac{Q}{( 1 - {ω}_{n}^{2} ( k ) ) + jQ [ ( 1 + λ ) {ω}_{n} ( k ) - {λω}_{n}^{3} ( k ) ]} .$$

Optionally, the duty cycle d(k+1) at the time k+1 is calculated by fitting an arctangent function:

$$d ( k + 1 ) = A \cdot arctan ( B ( {t}_{k + 1} - {t}_{k} ) ) + d ( k ) ;$$

where, tₖ₊₁−tₖ denotes a time of one sampling period; A denotes a time-varying factor; and B denotes an influence factor for a duty cycle change rate.

Optionally, the taking the error control variables e and ec as input values of a fuzzy controller, and acquiring an actual control variable hr output by the fuzzy controller includes:
determining membership values E and EC based on the error control variables e and ec and a membership function; and dividing the membership values E and EC both into five fuzzy subspaces, with linguistic values of: much smaller than a lower limit of a set range (NB), slightly smaller than the lower limit of the set range (NS), within the set range (ZO), slightly larger than an upper limit of the set range (PS), and much larger than the upper limit of the set range (PB);
determining a fuzzy output variable H based on the membership values E and EC; and dividing the fuzzy output variable H into five fuzzy subspaces, with linguistic values of: negative big (NB), negative small (NS), zero (ZO), positive small (PS), and positive big (PB); and
acquiring the actual control variable hr through defuzzification based on the fuzzy output variable H.

Optionally, controlling, after receiving an ignition signal, the plasma source system to operate in a constant-current output mode with a resonant frequency point, thereby igniting the reaction chamber includes:
controlling introduction of an excitation gas;
instantaneously reducing a resonant output current reference value

$${i}_{pri}^{*}$$

to a current reference value

$${i}_{pmin}^{*}$$

in a first preset time before an ignition operation;
driving, if the ignition signal is received, a relay S to close; and if not, allowing the system to continue to introduce the excitation gas;
comparing the resonant output current reference value

$${i}_{pri}^{*}$$

with a current value iₚᵣᵢ sampled by a power circuit to output a current error

$${e}_{1}^{*} ;$$

and starting a pulse-width modulation (PWM) driving unit after current proportional-integral (PI) modulation;
determining whether iₘᵢₙ≤iₚᵣᵢ≤iₘₐₓ is satisfied and maintained for more than a second preset time; if yes, determining whether the system is successfully ignited; and if not, determining that the ignition fails, and allowing the system to report an error and open the relay S;
adaptively adjusting, if the ignition is determined to be abnormal, a plasma ignition duration and an ignition voltage: increasing the ignition duration and the ignition voltage by a ratio of (1+K) in a cyclic manner; and
determining that, if the ignition is still not successful after exceeding an upper cycle limit, the ignition fails, and allowing the system to report an error and open the relay; and opening, if the ignition is successful, the relay, ending a constant-current stage, and entering a constant-power stage.

As can be seem from the above technical solution, the present disclosure adopts a hybrid control method of constant current and constant power, which can ionize multiple gases and provide a wide range of gas flow rates, thereby shortening process time and improving the applicability and etching rate of the remote plasma source.

A second aspect of the present disclosure provides a fuzzy hysteresis control circuit for a high-power, high-stability remote plasma source, using the fuzzy hysteresis control method for a remote plasma source in any one of the possible implementations in the first aspect, and including: a control unit, the PWM driving unit, the resonant converter, an ignition circuit, a sampling unit, the relay, and the reaction chamber, where
the control unit is configured to control the PWM driving unit to output a pulse signal and control the relay to close or open;
the resonant converter is configured to convert the pulse signal output by the PWM driving unit into an alternating current (AC) source and provide an input AC source for the ignition circuit;
the ignition circuit is configured to generate a high-voltage ignition signal to cause high-frequency oscillation ionization of a plasma load in the reaction chamber;
the sampling unit is configured to sample an ignition current of the ignition circuit, as well as an output voltage and an output current of the resonant converter;
the resonant converter includes a transformer T1; and the ignition circuit is connected with a secondary coil N3 of the transformer T1; and
the relay is controlled by the control unit to close or open.

Optionally, the fuzzy hysteresis control circuit further includes a sustaining circuit; the sustaining circuit is connected in series with a secondary coil N2 of the transformer T1; and the reaction chamber serves as a secondary side of the transformer T1 and provides only iₒ for the chamber, thereby ensuring a low-voltage energy input for the constant-power stage; and
the sustaining circuit is configured to sustain a stable bus voltage after a transition from the constant-current stage to the constant-power stage when the relay is opened.

With the above technical solutions, the present disclosure has the following beneficial effects.

The method provided by the present disclosure combines fuzzy control and the variable-bandwidth hysteresis comparator for control, and feedback compensation is applied to the output current and duty cycle D. The present disclosure can improve the power adjustment accuracy of the system, ensure a wide power range, enhance the operational stability of the remote plasma source, and improve the uniformity of semiconductor manufacturing processes.

The present disclosure adopts a hybrid control method of constant current and constant power, which can ionize multiple gases and provide a wide range of gas flow rates, thereby shortening process time and improving the applicability and etching rate of the remote plasma source.

### BRIEF DESCRIPTION OF THE DRAWINGS

In order to illustrate the specific embodiments of the present disclosure or the technical solutions in the prior art more clearly, drawings used in the description of the specific embodiments or the prior art will be briefly described below. In all the drawings, similar elements or portions are generally identified by similar reference numerals. In the drawings, each element or portion is not necessarily drawn to the actual scale.

FIG. 1 is a schematic diagram of a fuzzy hysteresis control circuit for a high-power, high-stability remote plasma source provided by an embodiment of the present disclosure;

FIG. 2 is a flowchart of a constant-current stage in a fuzzy hysteresis control method for a remote plasma source provided by an embodiment of the present disclosure;

FIG. 3 is a first flowchart of a constant-power stage in the fuzzy hysteresis control method for a remote plasma source provided by an embodiment of the present disclosure;

FIG. 4 is a second flowchart of the constant-power stage in the fuzzy hysteresis control method for a remote plasma source provided by an embodiment of the present disclosure;

FIG. 5 is a schematic diagram of a fuzzy controller provided by an embodiment of the present disclosure; and

FIGS. 6A-6C are schematic diagrams of a membership function provided by an embodiment of the present disclosure.

### DETAILED DESCRIPTION OF THE EMBODIMENTS

The embodiments of the technical solutions of the present disclosure will be described in detail below with reference to the drawings. The following embodiments are only used to more clearly illustrate the technical solutions of the present disclosure, and thus are merely exemplary and are not intended to limit the protection scope of the present disclosure.

It should be noted that the technical terms or scientific terms used herein should have the ordinary meanings as understood by those skilled in the art to which the present disclosure belongs, unless otherwise stated.

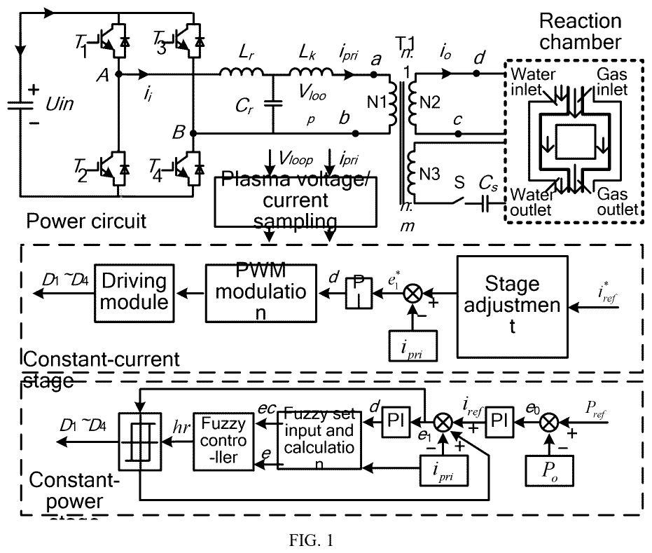

As shown in FIG. 1, the present embodiment provides a fuzzy hysteresis control circuit for a high-power remote plasma source, including: a remote plasma source power circuit, a constant-current stage unit, and a constant-power stage unit.

The remote plasma source power circuit includes a control unit, a pulse-width modulation (PWM) driving unit, a direct current (DC)/alternating current (AC) resonant converter, an ignition circuit, a sampling unit, and a reaction chamber.

The control unit is configured to control the PWM driving unit to output a pulse signal.

The PWM driving unit is configured to control an output current of the resonant converter.

The output current of the resonant converter is configured to affect an input current of the ignition circuit. The resonant converter is configured to convert a pulse signal output by the PWM driving unit into an AC source and provide an input AC source for the ignition circuit.

The ignition circuit is configured to generate a high-voltage ignition signal to cause high-frequency oscillation ionization of a plasma load. The resonant converter is configured to provide the input AC source.

The resonant converter includes transformer T1. The ignition circuit is connected with secondary coil N3 of the transformer T1.

The sampling unit is configured to sample an ignition current of the ignition circuit, as well as an output voltage and an output current of the resonant converter.

Relay S is controlled by the control unit to close or open.

The constant-current stage unit is configured to output, after receiving the ignition signal, a current and a duty cycle that keep a plasma source system operating around a resonant frequency point with a ±1% constant-current output, thereby igniting the reaction chamber.

The constant-power stage unit is configured to output a current and a duty cycle that keep the plasma source system operating in a constant-power output mode with a fixed frequency and a variable duty cycle when the reaction chamber is successfully ignited.

Optionally, the remote plasma source power circuit further includes a sustaining circuit. The sustaining circuit is connected in series with a secondary coil N2 of the transformer T. The vacuum reaction chamber serves as a secondary side of the high-frequency transformer and provides only iₒ for the chamber, thereby ensuring a low-voltage energy input for then ionization maintenance stage. The sustaining circuit is configured to sustain a stable bus voltage after a transition from the constant-current stage (ignition stage) to the constant-power stage (ionization stage) when the relay is opened.

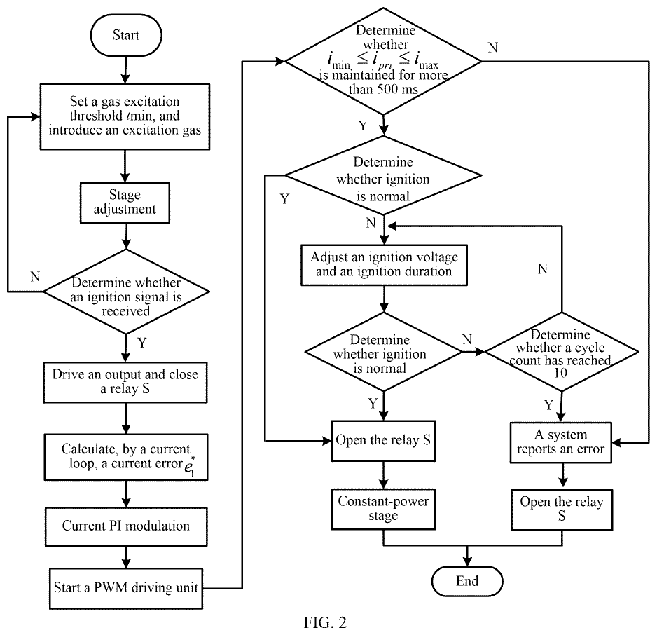

As shown in FIG. 2, the present embodiment provides a fuzzy hysteresis control method for a remote plasma source. After the ignition signal is received, the plasma source system is controlled to operate around the resonant frequency point with the ±1% constant-current output to ignite the reaction chamber. At this time, the system is in the constant-current stage, i.e., the ignition stage. The method includes following steps.

S110. After the remote plasma source is started, gas current excitation threshold iₘᵢₙ is first set in the system to control the introduction of an excitation gas.

S120. A stage adjustment unit instantaneously reduces resonant output current reference value

$${i}_{pri}^{*}$$

to current reference value

$${i}_{p min}^{*}$$

in 50 ms before the ignition operation. This step can effectively avoid an inrush current and protect the relay S.

S130. It is determined whether the ignition signal is received. When the ignition signal is received, the relay S is driven to close. Otherwise, the system continues to introduce the excitation gas.

S140. The resonant output current reference value

$${i}_{p r i}^{*}$$

is compared with the current value iₚᵣᵢ sampled by the power circuit to output current error

$${e}_{1}^{*} .$$

After current proportional-integral (PI) modulation, the PWM driving unit is started.

S150. It is determined whether iₘᵢₙ≤iₚᵣᵢ≤iₘₐₓ is satisfied and maintained for more than 500 ms. If yes, it is determined whether the system is successfully ignited. If not, it is determined that the ignition fails. The system reports an error and opens the relay S.

S160. If the ignition is determined to be abnormal, a plasma ignition duration and an ignition voltage are adaptively adjusted. The ignition duration and the ignition voltage are increased by a ratio of (1+K) in a cyclic manner. An upper limit for the number of cycles is 10 to improve the ignition success rate.

S170. If the ignition is still not successful after exceeding the upper cycle limit, it is determined that the ignition fails. The system reports an error and opens the relay. If the ignition is successful, the relay is opened, the constant-current stage is ended, and the system enters the constant-power stage.

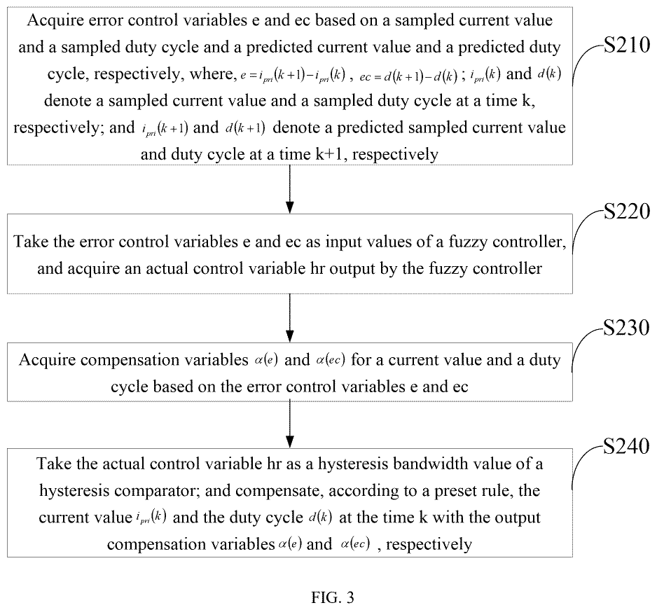

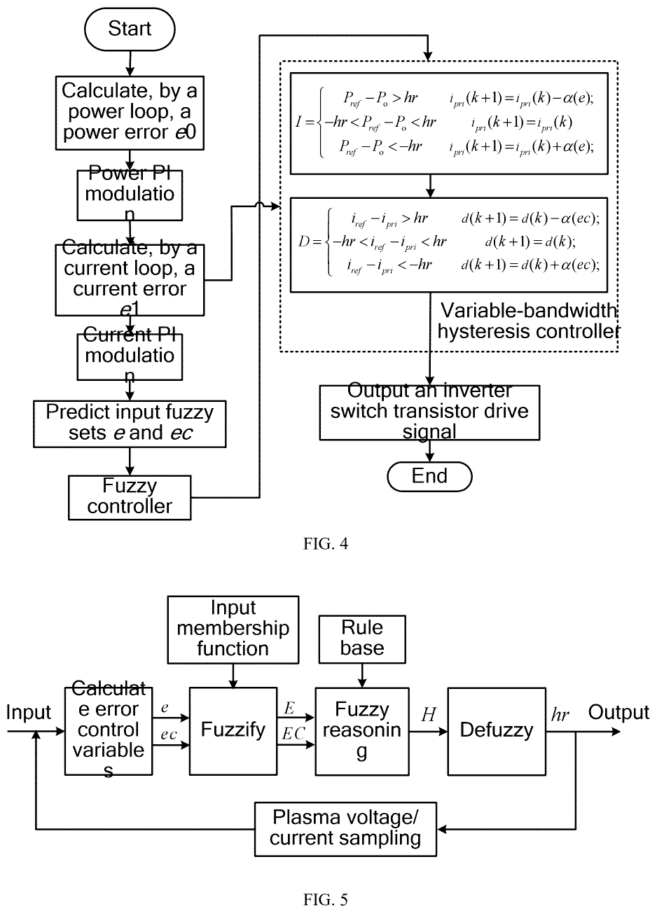

As shown in FIGS. 3 and 4, in the fuzzy hysteresis control method for a remote plasma source provided by the present embodiment, when the reaction chamber is successfully ignited, the plasma source system is controlled to operate in the constant-power output mode with the fixed frequency and the variable duty cycle. This includes following steps.

S210. Error control variables e and ec are acquired based on a sampled current value and a sampled duty cycle and a predicted current value and a predicted duty cycle, respectively.
where, e=iₚᵣᵢ(k+1)−iₚᵣᵢ(k), ec=d(k+1)−d(k); iₚᵣᵢ(k) and d(k) denote a sampled current value and a sampled duty cycle at time k, respectively, and iₚᵣᵢ(k+1) and d(k+1) denote a predicted sampled current value and duty cycle at time k+1, respectively.

Specifically, iₚᵣᵢ(k+1) at the time k+1 is predicted by the following method.

In this embodiment, the resonant converter is an inductor-capacitor-inductor (LCL) resonant converter. Due to the resonance effect of the converter, normalized value ωₙ of resonant frequency ω₀ and switching frequency ω of the converter is defined as:

ω₀=1/\sqrt{LᵣCᵣ}; ωₙ=ω/ω₀=2fₛ\sqrt{LᵣCᵣ}; where, fₛ denotes an output frequency.

Equivalent resistance R_{L} and a root mean square (RMS) value of a fundamental component of an input square wave voltage are expressed as:

$${R}_{L} = {n}^{2} {R}_{p} ; {U}_{a b} = \frac{2 \sqrt{2}}{π} {U}_{i n} ;$$

Inductance ratio λ, characteristic impedance Z₀, and quality factor Q of an equivalent circuit are respectively:

$$λ = \frac{{L}_{k}}{{L}_{r}} ; {Z}_{0} = \sqrt{\frac{{L}_{r}}{{C}_{r}}} ; Q = \frac{{ω}_{0} {L}_{r}}{{R}_{p}} = \frac{{Z}_{0}}{{n}^{2} {R}_{p}} = \sqrt{\frac{{L}_{r}}{{C}_{r}}} / {R}_{L} ;$$

where, Lᵣ, Cᵣ, and Lₖ denote a resonant inductance, a resonant capacitance, and a leakage inductance of the resonant converter, respectively.

Primary winding current value iₚᵣᵢ and voltage Vₗₒₒₚ are:

$${i}_{pri} = \frac{{U}_{a b}}{{Z}_{0}} \frac{Q}{( 1 - {ω}_{n}^{2} ) + jQ [ ( 1 + λ ) {ω}_{n} - {λω}_{n}^{3} ]} ,$$

$${V}_{l o o p} = {U}_{a b} \frac{1}{( 1 - {ω}_{n}^{2} ) + jQ [ ( 1 + λ ) {ω}_{n} - λ {ω}_{n}^{3} ]} ,$$

The primary winding current value at the time k+1 is predicted as

$${i}_{pri} ( k + 1 ) = \frac{{U}_{a b}}{{Z}_{0}} \frac{Q}{( 1 - {ω}_{n}^{2} ( k ) ) + jQ [ ( 1 + λ ) {ω}_{n} ( k ) - {λω}_{n}^{3} ( k ) ]} .$$

According to the characteristics of the LCL resonant circuit, when the frequency is fixed, the resonant current value iₚᵣᵢ remains relatively constant.

The actual power Pₒ(k) at the time k can be expressed by iₚᵣᵢ(k) and Vₗₒₒₚ (k) sampled from the plasma voltage/current:

Pₒ(k)=iₚᵣᵢ(k)·Vₗₒₒₚ(k)·δ
where, δ denotes a vector angle between the current value iₚᵣᵢ and the voltage Vₗₒₒₚ, taking a value of 0.65≤δ≤0.95.

The duty cycle d(k) at the current time k is calculated by feeding current error e1 in a current loop into the current PI modulation. The duty cycle d(k) at the time k+1 is predicted by fitting the duty cycle d(k+1) of a measured object at the current time k.

The duty cycle d(k+1) at the time k+1 is calculated by fitting an arctangent function:

d(k+1)=A·arctan(B(tₖ₊₁−tₖ)+d(k);
where, tₖ₊₁−tₖ denotes a time of one sampling period; A denotes a time-varying factor; and B denotes an influence factor for a duty cycle change rate.

S220. The error control variables e and ec serve as input values of the fuzzy controller to acquire actual control variable hr output by the fuzzy controller.

The fuzzy controller quantifies and calculates the input variable and the feedback variable to acquire the system errors e and ec, which are used as inputs to the fuzzy controller. The control variables are fuzzified, a fuzzy universe and a corresponding membership function are determined, and E and EC are acquired. Based on a pre-established fuzzy control rule, decision-making is performed to acquire fuzzy output variable H. The fuzzy output variable His defuzzified to acquire the actual control variable hr, which is sent to a control mechanism to complete the entire control process.

The input fuzzy sets e and ec of the fuzzy controller and the fuzzy set of the output variable H are as follows.

In this embodiment, bandwidth hr of the hysteresis controller is controlled based on a difference between the resonant output current reference value iref and the sampled current value ipri. The input fuzzy sets e and ec are divided into five fuzzy subspaces, with linguistic values of: much smaller than a lower limit of a set range (NB), slightly smaller than the lower limit of the set range (NS), within the set range (ZO), slightly larger than an upper limit of the set range (PS), and much larger than the upper limit of the set range (PB). The hysteresis width hr is divided into five fuzzy subspaces, with linguistic values of: negative big (NB), negative small (NS), zero (ZO), positive small (PS), and positive big (PB). Then:
e [symbol] ec={NB, NS, ZO, PS, PB}
hr={NB, NS, ZO, PS, PB};

The basic universe of the input fuzzy sets e and ec is [−1,1], and the basic universe of the hysteresis width hr is [−1,1]. To ensure high sensitivity of the fuzzy controller, at the boundaries of the basic universe, the input membership functions of each variable are selected as highly sensitive triangular functions and are uniformly distributed.

The step S220 specifically includes following sub-steps.

S221. Based on the error control variables e and ec and the membership function, the membership values E and EC are determined. The membership values E and EC are both divided into five fuzzy subspaces, with linguistic values of: much smaller than a lower limit of a set range (NB), slightly smaller than the lower limit of the set range (NS), within the set range (ZO), slightly larger than an upper limit of the set range (PS), and much larger than the upper limit of the set range (PB).

S222. Based on the membership values E and EC, the fuzzy output variable H is determined. The fuzzy output variable His divided into five fuzzy subspaces, with linguistic values of: negative big (NB), negative small (NS), zero (ZO), positive small (PS), and positive big (PB).

S223. Based on the fuzzy output variable H, the actual control variable hr is acquired through defuzzification.

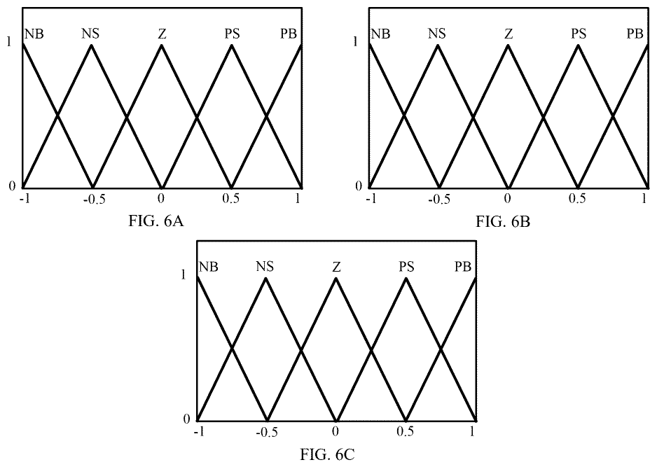

FIG. 6A-6C show the membership functions of the output quantities E, EC, and H in the fuzzy rule base of the fuzzy controller, respectively. Table 1 shows the fuzzy rule base of the fuzzy sets E, EC and the fuzzy output variable H.

TABLE 1

EC

| | | | | | |
|---|---|---|---|---|---|
| H | NB | NS | ZO | PS | PB |

| | | | | | | |
|---|---|---|---|---|---|---|
| E | NB | PB | PB | PB | PS | ZO |
| | NS | PB | PB | PS | ZO | NS |
| | ZO | PS | PS | ZO | NS | NS |
| | PS | PS | ZO | NS | NB | NB |
| | PB | ZO | NS | NB | NB | NB |

The fuzzy reasoning method used in this embodiment is the Mamdani reasoning method. The Mamdani reasoning method is a commonly used method in fuzzy control, and is inherently a synthetic reasoning method. The i-th rule in the rule base is expressed as:

Ri “If e is E and ec is EC, Then hr is H”
where, e, ec, and hr are the linguistic variables corresponding to E, EC, and H, respectively.
where, hr is the fuzzy output variable, and the inherent fuzzy relationship is:

Rᵢ=(eᵢ×ecᵢ)×hrᵢ

The specific step of fuzzy reasoning is as follows. Based on the set rule R, fuzzy reasoning is performed on the fuzzy input quantities E and EC to output the fuzzy output variable H:

H=(E×EC)∘R.

The inherent fuzzy relationship of the entire rule base is:

$$R = {⋃}_{i = 1}^{n} {R}_{i}$$

The specific step of defuzzification is as follows. Based on a center of gravity method, the center of gravity value of each element in the fuzzy output variable H and its corresponding membership are found to acquire the output variable hr.

$$hr = \frac{\sum {x}_{i} \cdot {u}_{j}}{\sum {u}_{j}}$$

where, hr is the output variable of the fuzzy controller, xᵢ is the center value of the interval corresponding to the membership function of the output variable, and uᵢ is the membership corresponding to xᵢ.

The output variable hr is acquired as follows. First, the input signal is fuzzified. Then, based on the set data set and rule set, fuzzy reasoning is performed to acquire the fuzzy output variable H. Finally, the center of gravity method is used to defuzzify the fuzzy output variable H, thereby finally acquiring the output variable hr.

S230. A compensation variable α(e) for the predicted current value at the next time and a compensation variable α(ec) for the predicted duty cycle at the next time are acquired based on the error control variables e and ec.

In this step, the compensation variables α(e) and α(ec) are positively correlated with the error control variables e and ec, and are specifically determined as follows:

α(e)=m·e 0.9<m<1.1

α(ec)=n·ec 0.9<n<1.1
where, m and n are correlation coefficients, which can be selected by those skilled in the art based on actual application conditions.

S240. The actual control variable hr is used as a hysteresis bandwidth value of the hysteresis comparator, and the compensation variables α(e) and α(ec) are output according to a preset rule to compensate the current value iₚᵣᵢ(k) and the duty cycle d(k) at time k, respectively.

After fuzzy reasoning, hr is acquired as the hysteresis bandwidth value of the hysteresis comparator. At this time, the rule of the variable hysteresis bandwidth hysteresis comparator includes:

$$I = \{ \begin{matrix}{P}_{ref} - {P}_{o} > hr & {i}_{pri} ( k + 1 ) = {i}_{pri} ( k ) - α ( e ) ; \\ - hr \leq {P}_{ref} - {P}_{o} \leq hr & {i}_{pri} ( k + 1 ) = {i}_{pri} ( k ) - α ( e ) ; \\ {P}_{ref} - {P}_{o} < - hr & {i}_{pri} ( k + 1 ) = {i}_{pri} ( k ) + α ( e ) ;\end{matrix}$$

$$D = \{ \begin{matrix}{i}_{ref} - {i}_{pri} > hr & d ( k + 1 ) = d ( k ) - α ( ec ) ; \\ - hr \leq {i}_{ref} - {i}_{pri} \leq hr & d ( k + 1 ) = d ( k ) - α ( ec ) ; \\ {i}_{ref} - {i}_{pri} < - hr & d ( k + 1 ) = d ( k ) + α ( ec ) ;\end{matrix}$$

In a specific rule, the current value iₚᵣᵢ(k) at the current time is compensated with the output compensation variable α(e), and the duty cycle d(k) at the current time is compensated with the output compensation variable α(ec).

When the current value iₚᵣᵢ(k) at the current time is compensated with the output compensation variable α(e), the preset rule is specifically as follows.

When the power error P_{ref}−Pₒ>hr, the variable α(e) is subtracted from the current value iₚᵣᵢ(k) at the current time and fed back to compensate the output current value iₚᵣᵢ(k+1) at the next time.

When the power error −hr≤P_{ref}−Pₒ≤hr, iₚᵣᵢ(k+1) at the time k+1 is maintained consistent with iₚᵣᵢ(k) at the time k.

When the power error P_{ref}−Pₒ<−hr, the variable α(e) is added to the current value iₚᵣᵢ(k) at the current time and fed back to compensate the output current value iₚᵣᵢ(k+1) at the next time.

Specifically, the actual output power Pₒ is calculated based on the sampled output voltage and current, and iₚᵣᵢ(k+1) at the time k+1 is compared with iₚᵣᵢ(k) at the time k to acquire the current error e. The compensation variable α(e) for the output variable of the power loop is calculated from the current error e. When the power error output by the power loop satisfies P_{ref}−Pₒ>hr, the variable α(e) is subtracted from the current value iₚᵣᵢ(k) at the current time and fed back to compensate the output current value iₚᵣᵢ(k+1) at the next time. When the power error satisfies −hr≤P_{ref}−Pₒ≤hr, iₚᵣᵢ(k+1) at the time k+1 is maintained consistent with iₚᵣᵢ(k) at the time k. When the power error satisfies P_{ref}−Pₒ<−hr, the variable α(e) is added to the current value iₚᵣᵢ(k) at the current time and fed back to compensate the output current value iₚᵣᵢ(k+1) at the next time.

When the duty cycle d(k) at the current time is compensated with the output compensation variable α(ec), the preset rule is specifically as follows.

When the current error satisfies i_{ref}−iₚᵣᵢ>hr, the variable α(ec) is subtracted from the duty cycle d(k) at the current time and fed back to compensate the output duty cycle d(k+1) at the next time.

When the current error satisfies −hr≤i_{ref}−iₚᵣᵢ≤hr, the switch transistor state of the previous time is maintained to keep the duty cycle D relatively stable.

When the current error satisfies i_{ref}−iₚᵣᵢ<−hr, the variable α(ec) is added to the duty cycle d(k) at the current time and fed back to compensate the output duty cycle d(k+1) at the next time.

Specifically, bias compensation is performed on the current loop. The duty cycle d(k+1) at the time k+1 is compared with d(k) at the time k to acquire the duty cycle error ec. The compensation variable α(ec) for the output variable of the current loop is calculated from the duty cycle error ec. When i_{ref}−iₚᵣᵢ>hr, the variable α(ec) is subtracted from the duty cycle d(k) at the current time and fed back to compensate the output duty cycle d(k+1) at the next time. That is, T1 and T3 are turned off, and T2 and T4 are turned on to reduce the duty cycle D. When the current error satisfies −hr≤i_{ref}−iₚᵣᵢ≤hr, the switch transistor state of the previous time is maintained to keep the duty cycle D relatively stable. When the current error satisfies i_{ref}−iₚᵣᵢ<−hr, the variable α(ec) is added to the duty cycle d(k) at the current time and fed back to compensate the output duty cycle d(k+1) at the next time. That is, T1 and T3 are turned on, and T2 and T4 are turned off to increase the duty cycle D.

The embodiments described above are merely intended to describe the technical solutions of the present disclosure in detail, but the description of the foregoing embodiments is merely intended to facilitate the understanding of the method of the present disclosure, and shall not be construed as a limitation to the embodiments of the present disclosure. Any variation or replacement readily figured out by a person skilled in the art shall fall within the protection scope of the embodiments of the present disclosure.

1. A fuzzy hysteresis control method for a high-power, high-stability remote plasma source, comprising: controlling, after receiving an ignition signal, a plasma source system to operate in a constant-current output mode with a resonant frequency point, thereby igniting a reaction chamber, and controlling the plasma source system to operate in a constant-power output mode with a fixed frequency and a variable duty cycle when the reaction chamber is successfully ignited, comprising:
acquiring error control variables e and ec based on a sampled current value and a sampled duty cycle and a predicted current value and a predicted duty cycle, respectively, wherein, e=iₚᵣᵢ(k+1)−iₚᵣᵢ(k), ec=d(k+1)−d(k); iₚᵣᵢ(k) and d(k) denote a sampled current value and a sampled duty cycle at a time k, respectively; and iₚᵣᵢ(k+1) and d(k+1) denote a predicted sampled current value and duty cycle at a time k+1, respectively;
taking the error control variables e and ec as input values of a fuzzy controller, and acquiring an actual control variable hr output by the fuzzy controller;
acquiring a compensation variable α(e) for the predicted current value at the next time and a compensation variable α(ec) for the predicted duty cycle at the next time based on the error control variables e and ec; and
taking the actual control variable hr as a hysteresis bandwidth value of a hysteresis comparator; and compensating, according to a preset rule, the current value iₚᵣᵢ(k) and the duty cycle d(k) at the time k with the output compensation variables α(e) and α(ec), respectively.

2. The fuzzy hysteresis control method according to claim 1, wherein when the current value iₚᵣᵢ(k) at the current time is compensated with the output compensation variable α(e), the preset rule comprises:
when a power error satisfies P_{ref}−Pₒ>hr, the variable α(e) is subtracted from the current value iₚᵣᵢ(k) at the current time and fed back to compensate the output current value iₚᵣᵢ(k+1) at the next time;
when the power error satisfies −hr≤P_{ref}−Pₒ≤hr, iₚᵣᵢ(k+1) at the time k+1 is maintained consistent with iₚᵣᵢ(k) at the time k; and
when the power error satisfies P_{ref}−Pₒ<−hr, the variable α(e) is added to the current value iₚᵣᵢ(k) at the current time and fed back to compensate the output current value iₚᵣᵢ(k+1) at the next time.

3. The fuzzy hysteresis control method according to claim 2, wherein when the duty cycle d(k) at the current time is compensated with the output compensation variable α(ec), the preset rule comprises:
when a current error satisfies i_{ref}−iₚᵣᵢ>hr, the variable α(ec) is subtracted from the duty cycle d(k) at the current time and fed back to compensate the output duty cycle d(k+1) at the next time;
when the current error satisfies −hr≤i_{ref}−iₚᵣᵢ≤hr, a switch transistor state of a previous time is maintained to keep the duty cycle D relatively stable; and
when the current error satisfies i_{ref}−iₚᵣᵢ<−hr, the variable α(ec) is added to the duty cycle d(k) at the current time and fed back to compensate the output duty cycle d(k+1) at the next time.

4. The fuzzy hysteresis control method according to claim 1, wherein iₚᵣᵢ(k+1) at the time k+1 is predicted as follows:
expressing a normalized value ωₙ of a resonant frequency ω₀ and a switching frequency ω of a resonant converter as follows:
ω₀=1/\sqrt{LᵣCᵣ}; ωₙ=ω/ω₀=2fₛ\sqrt{LᵣCᵣ}; wherein, fₛ denotes an output frequency;
expressing an equivalent resistance R_{L} and a root mean square (RMS) value of a fundamental component of an input square wave voltage as follows:
$${R}_{L} = {n}^{2} {R}_{p} ; {U}_{a b} = \frac{2 \sqrt{2}}{π} {U}_{i n} ;$$
expressing an inductance ratio λ, a characteristic impedance Z₀, and a quality factor Q of an equivalent circuit as follows:
$$λ = \frac{{L}_{k}}{{L}_{r}} ; {Z}_{0} = \sqrt{\frac{{L}_{r}}{{C}_{r}}} ; Q = \frac{{ω}_{0} {L}_{r}}{{R}_{p}} = \frac{{Z}_{0}}{{n}^{2} {R}_{p}} = \sqrt{\frac{{L}_{r}}{{C}_{r}}} / {R}_{L} ;$$
wherein, Lᵣ, Cᵣ, and Lₖ denote a resonant inductance, a resonant capacitance, and a leakage inductance of the resonant converter, respectively;
expressing a primary winding current value iₚᵣᵢ and a voltage Vₗₒₒₚ as follows:
$${i}_{pri} = \frac{{U}_{a b}}{{Z}_{0}} \frac{Q}{( 1 - {ω}_{n}^{2} ) + jQ [ ( 1 + λ ) {ω}_{n} - {λω}_{n}^{3} ]} ;$$
$${V}_{l o o p} = {U}_{a b} \frac{1}{( 1 - {ω}_{n}^{2} ) + jQ [ ( 1 + λ ) {ω}_{n} - λ {ω}_{n}^{3} ]} ;$$
and
predicting the primary winding current value at the time k+1 as
$${i}_{pri} ( k + 1 ) = \frac{{U}_{a b}}{{Z}_{0}} \frac{Q}{( 1 - {ω}_{n}^{2} ( k ) ) + jQ [ ( 1 + λ ) {ω}_{n} ( k ) - {λω}_{n}^{3} ( k ) ]} .$$

5. The fuzzy hysteresis control method according to claim 4, wherein the duty cycle d(k+1) at the time k+1 is calculated by fitting an arctangent function:
d(k+1)=A·arctan(B(tₖ₊₁−tₖ))+d(k);
wherein, tₖ₊₁−tₖ denotes a time of one sampling period; A denotes a time-varying factor;
and B denotes an influence factor for a duty cycle change rate.

6. The fuzzy hysteresis control method according to claim 1, wherein the taking the error control variables e and ec as the input values of the fuzzy controller, and acquiring the actual control variable hr output by the fuzzy controller comprises:
determining membership values E and EC based on the error control variables e and ec and a membership function; and dividing the membership values E and EC both into five fuzzy subspaces, with linguistic values of: much smaller than a lower limit of a set range (NB), slightly smaller than the lower limit of the set range (NS), within the set range (ZO), slightly larger than an upper limit of the set range (PS), and much larger than the upper limit of the set range (PB);
determining a fuzzy output variable H based on the membership values E and EC; and dividing the fuzzy output variable H into five fuzzy subspaces, with linguistic values of: negative big (NB), negative small (NS), zero (ZO), positive small (PS), and positive big (PB); and
acquiring the actual control variable hr through defuzzification based on the fuzzy output variable H.

7. The fuzzy hysteresis control method according to claim 1, wherein the controlling, after receiving the ignition signal, the plasma source system to operate in the constant-current output mode with the resonant frequency point, thereby igniting the reaction chamber comprises:
controlling introduction of an excitation gas;
instantaneously reducing a resonant output current reference value
$${i}_{pri}^{*}$$
to a current reference value
$${i}_{pmin}^{*}$$
in a first preset time before an ignition operation;
driving, if the ignition signal is received, a relay S to close; and otherwise, allowing the system to continue to introduce the excitation gas;
comparing the resonant output current reference value
$${i}_{pri}^{*}$$
with a current value iₚᵣᵢ sampled by a power circuit to output a current error
$${e}_{1}^{*} ;$$
and starting a pulse-width modulation (PWM) driving unit after current proportional-integral (PI) modulation;
determining whether iₘᵢₙ≤iₚᵣᵢ≤iₘₐₓ is satisfied and maintained for more than a second preset time; if yes, determining whether the system is successfully ignited; and if not, determining that the ignition fails, and allowing the system to report an error and open the relay S;
adaptively adjusting, if the ignition is determined to be abnormal, a plasma ignition duration and an ignition voltage: increasing the plasma ignition duration and the ignition voltage by a ratio of (1+K) in a cyclic manner; and
determining that, if the ignition is still not successful after exceeding an upper cycle limit, the ignition fails, and allowing the system to report an error and open the relay; and opening, if the ignition is successful, the relay, ending a constant-current stage, and entering a constant-power stage.

8. A fuzzy hysteresis control circuit for a remote plasma source, using the fuzzy hysteresis control method for the high-power, high-stability remote plasma source according to claim 1, and comprising: a control unit, the PWM driving unit, the resonant converter, an ignition circuit, a sampling unit, the relay, and the reaction chamber, wherein
the control unit is configured to control the PWM driving unit to output a pulse signal and control the relay to close or open;
the resonant converter is configured to convert the pulse signal output by the PWM driving unit into an alternating current (AC) source and provide an input AC source for the ignition circuit;
the ignition circuit is configured to generate a high-voltage ignition signal to cause high-frequency oscillation ionization of a plasma load in the reaction chamber;
the sampling unit is configured to sample an ignition current of the ignition circuit, as well as an output voltage and an output current of the resonant converter;
the resonant converter comprises a transformer T1; and the ignition circuit is connected with a secondary coil N3 of the transformer T1; and
the relay is controlled by the control unit to close or open.

9. The fuzzy hysteresis control circuit according to claim 8, further comprising a sustaining circuit, wherein the sustaining circuit is connected in series with a secondary coil N2 of the transformer T1; and the reaction chamber serves as a secondary side of the transformer T1 and provides only iₒ for the reaction chamber, thereby ensuring a low-voltage energy input for the constant-power stage; and
the sustaining circuit is configured to sustain a stable bus voltage after a transition from the constant-current stage to the constant-power stage when the relay is opened.

10. The fuzzy hysteresis control method according to claim 3, wherein iₚᵣᵢ(k+1) at the time k+1 is predicted as follows:
expressing a normalized value ωₙ of a resonant frequency ω₀ and a switching frequency ω of a resonant converter as follows:
ω₀=1/\sqrt{LᵣCᵣ}; ωₙ=ω/ω₀=2fₛ\sqrt{LᵣCᵣ}; wherein, fₛ denotes an output frequency;
expressing an equivalent resistance R_{L} and a root mean square (RMS) value of a fundamental component of an input square wave voltage as follows:
$${R}_{L} = {n}^{2} {R}_{p} ; {U}_{ab} = \frac{2 \sqrt{2}}{π} {U}_{in} ;$$
expressing an inductance ratio λ, a characteristic impedance Z₀, and a quality factor Q of an equivalent circuit as follows:
$$λ = \frac{{L}_{k}}{{L}_{r}} ; {Z}_{0} = \sqrt{\frac{{L}_{r}}{{C}_{r}}} ; Q = \frac{{ω}_{0} {L}_{r}}{{R}_{p}} = \frac{{Z}_{0}}{{n}^{2} {R}_{p}} = \sqrt{\frac{{L}_{r}}{{C}_{r}}} / {R}_{L} ;$$
wherein, Lᵣ, Cᵣ, and Lₖ denote a resonant inductance, a resonant capacitance, and a leakage inductance of the resonant converter, respectively;
expressing a primary winding current value iₚᵣᵢ and a voltage Vₗₒₒₚ as follows:
$${i}_{pri} = \frac{{U}_{ab}}{{Z}_{0}} \frac{Q}{( 1 - {ω}_{n}^{2} ) + jQ [ ( 1 + λ ) {ω}_{n} - λ {ω}_{n}^{3} ]} ;$$
$${V}_{loop} = {U}_{ab} \frac{1}{( 1 - {ω}_{n}^{2} ) + jQ [ ( 1 + λ ) {ω}_{n} - λ {ω}_{n}^{3} ]} ;$$
and
predicting the primary winding current value at the time k+1 as
$${i}_{pri} ( k + 1 ) = \frac{{U}_{ab}}{{Z}_{0}} \frac{Q}{( 1 - {ω}_{n}^{2} ( k ) ) + jQ [ ( 1 + λ ) {ω}_{n} ( k ) - {λω}_{n}^{3} ( k ) ]} .$$

11. The fuzzy hysteresis control circuit according to claim 8, wherein when the current value iₚᵣᵢ(k) at the current time is compensated with the output compensation variable α(e), the preset rule comprises:
when a power error satisfies P_{ref}−Pₒ>hr, the variable α(e) is subtracted from the current value iₚᵣᵢ(k) at the current time and fed back to compensate the output current value iₚᵣᵢ(k+1) at the next time;
when the power error satisfies −hr≤P_{ref}−Pₒ≤hr, iₚᵣᵢ(k+1) at the time k+1 is maintained consistent with iₚᵣᵢ(k) at the time k; and
when the power error satisfies P_{ref}−Pₒ<−hr, the variable α(e) is added to the current value iₚᵣᵢ(k) at the current time and fed back to compensate the output current value iₚᵣᵢ(k+1) at the next time.

12. The fuzzy hysteresis control circuit according to claim 11, wherein when the duty cycle d(k) at the current time is compensated with the output compensation variable α(ec), the preset rule comprises:
when a current error satisfies i_{ref}−iₚᵣᵢ>hr, the variable α(ec) is subtracted from the duty cycle d(k) at the current time and fed back to compensate the output duty cycle d(k+1) at the next time;
when the current error satisfies −hr≤i_{ref}−iₚᵣᵢ≤hr, a switch transistor state of a previous time is maintained to keep the duty cycle D relatively stable; and
when the current error satisfies i_{ref}−iₚᵣᵢ<−hr, the variable α(ec) is added to the duty cycle d(k) at the current time and fed back to compensate the output duty cycle d(k+1) at the next time.

13. The fuzzy hysteresis control circuit according to claim 8, wherein iₚᵣᵢ(k+1) at the time k+1 is predicted as follows:
expressing a normalized value ωₙ of a resonant frequency ω₀ and a switching frequency ω of a resonant converter as follows:
ω₀=1/\sqrt{LᵣCᵣ}; ωₙ=ω/ω₀=2fₛ\sqrt{LᵣCᵣ}; wherein, fₛ denotes an output frequency;
expressing an equivalent resistance R_{L} and a root mean square (RMS) value of a fundamental component of an input square wave voltage as follows:
$${R}_{L} = {n}^{2} {R}_{p} ; {U}_{ab} = \frac{2 \sqrt{2}}{π} {U}_{in} ;$$
expressing an inductance ratio λ, a characteristic impedance Z₀, and a quality factor Q of an equivalent circuit as follows:
$$λ = \frac{{L}_{k}}{{L}_{r}} ; {Z}_{0} = \sqrt{\frac{{L}_{r}}{{C}_{r}}} ; Q = \frac{{ω}_{0} {L}_{r}}{{R}_{p}} = \frac{{Z}_{0}}{{n}^{2} {R}_{p}} = \sqrt{\frac{{L}_{r}}{{C}_{r}}} / {R}_{L} ;$$
wherein, Lᵣ, Cᵣ, and Lₖ denote a resonant inductance, a resonant capacitance, and a leakage inductance of the resonant converter, respectively;
expressing a primary winding current value iₚᵣᵢ and a voltage Vₗₒₒₚ as follows:
$${i}_{pri} = \frac{{U}_{ab}}{{Z}_{0}} \frac{Q}{( 1 - {ω}_{n}^{2} ) + jQ [ ( 1 + λ ) {ω}_{n} - λ {ω}_{n}^{3} ]} ;$$
$${V}_{loop} = {U}_{ab} \frac{1}{( 1 - {ω}_{n}^{2} ) + jQ [ ( 1 + λ ) {ω}_{n} - λ {ω}_{n}^{3} ]} ;$$
and
predicting the primary winding current value at the time k+1 as
$${i}_{pri} ( k + 1 ) = \frac{{U}_{ab}}{{Z}_{0}} \frac{Q}{( 1 - {ω}_{n}^{2} ( k ) ) + jQ [ ( 1 + λ ) {ω}_{n} ( k ) - {λω}_{n}^{3} ( k ) ]} .$$

14. The fuzzy hysteresis control circuit according to claim 13, wherein the duty cycle d(k+1) at the time k+1 is calculated by fitting an arctangent function:
d(k+1)=A·arctan(B(tₖ₊₁−tₖ)+d(k);
wherein, tₖ₊₁−tₖ denotes a time of one sampling period; A denotes a time-varying factor;
and B denotes an influence factor for a duty cycle change rate.

15. The fuzzy hysteresis control circuit according to claim 8, wherein the taking the error control variables e and ec as the input values of the fuzzy controller, and acquiring the actual control variable hr output by the fuzzy controller comprises:
determining membership values E and EC based on the error control variables e and ec and a membership function; and dividing the membership values E and EC both into five fuzzy subspaces, with linguistic values of: much smaller than a lower limit of a set range (NB), slightly smaller than the lower limit of the set range (NS), within the set range (ZO), slightly larger than an upper limit of the set range (PS), and much larger than the upper limit of the set range (PB);
determining a fuzzy output variable H based on the membership values E and EC; and dividing the fuzzy output variable H into five fuzzy subspaces, with linguistic values of: negative big (NB), negative small (NS), zero (ZO), positive small (PS), and positive big (PB); and
acquiring the actual control variable hr through defuzzification based on the fuzzy output variable H.

16. The fuzzy hysteresis control circuit according to claim 8, wherein the controlling, after receiving the ignition signal, the plasma source system to operate in the constant-current output mode with the resonant frequency point, thereby igniting the reaction chamber comprises:
controlling introduction of an excitation gas;
instantaneously reducing a resonant output current reference value
$${i}_{pri}^{*}$$
to a current reference value
$${i}_{pmin}^{*}$$
in a first preset time before an ignition operation;
driving, if the ignition signal is received, a relay S to close; and otherwise, allowing the system to continue to introduce the excitation gas;
comparing the resonant output current reference value
$${i}_{pri}^{*}$$
with a current value iₚᵣᵢ sampled by a power circuit to output a current error
$${e}_{1}^{*} ;$$
and starting a pulse-width modulation (PWM) driving unit after current proportional-integral (PI) modulation;
determining whether iₘᵢₙ≤iₚᵣᵢ≤iₘₐₓ is satisfied and maintained for more than a second preset time; if yes, determining whether the system is successfully ignited; and if not, determining that the ignition fails, and allowing the system to report an error and open the relay S;
adaptively adjusting, if the ignition is determined to be abnormal, a plasma ignition duration and an ignition voltage: increasing the plasma ignition duration and the ignition voltage by a ratio of (1+K) in a cyclic manner; and
determining that, if the ignition is still not successful after exceeding an upper cycle limit, the ignition fails, and allowing the system to report an error and open the relay; and opening, if the ignition is successful, the relay, ending a constant-current stage, and entering a constant-power stage.
